(19) United States
(12) Patent Application Publication
(10) Pub. No.: US 2023/0009090 A1
(43) Pub. Date: Jan. 12, 2023

(54) SEMICONDUCTOR DEVICE LAYOUT STRUCTURE AND METHOD OF FORMING SEMICONDUCTOR DEVICE

(71) Applicant: CHANGXIN MEMORY TECHNOLOGIES, INC., Hefei City, (CN)

(72) Inventor: Haibo CHEN, Hefei City (CN)

(21) Appl. No.: 17/453,892

(22) Filed: Nov. 8, 2021

Related U.S. Application Data
(63) Continuation of application No. PCT/CN2021/106488, filed on Jul. 15, 2021.

(30) Foreign Application Priority Data
Jul. 12, 2021 (CN) 202110782915.2

(51) Int. Cl. H01L 27/02; H01L 21/8234; H01L 21/66

(52) U.S. Cl. CPC H01L 27/0207; H01L 21/823475; H01L 22/32

(57) ABSTRACT

The present application relates to the field of semiconductors, and discloses a semiconductor device layout structure and a method of forming a semiconductor device. The semiconductor device layout structure includes: an active area layout layer and a plurality of subdevice layout layers located on the active area layout layer, wherein each of the subdevice layout layers includes a gate pattern region, a source pattern region, and a drain pattern region; and the gate pattern regions of at least two of the subdevice layout layers are connected together and form a gate connection pattern region, the source pattern regions of the at least two of the subdevice layout layers are connected together and form a source connection pattern region, the gate connection pattern region is connected to a gate test terminal, and the source connection pattern region is connected to a source test terminal.

### CROSS-REFERENCE TO RELATED APPLICATIONS

This is a continuation of International Application No. PCT/CN2021/106488, filed on Jul. 15, 2021, which claims the priority to Chinese Patent Application No. 202110782915.2, titled “SEMICONDUCTOR DEVICE LAYOUT STRUCTURE AND METHOD OF FORMING SEMICONDUCTOR DEVICE”, filed with the China National Intellectual Property Administration (CNIPA) on Jul. 12, 2021. The entire contents of International Application No. PCT/CN2021/106488 and Chinese Patent Application No. 202110782915.2 are incorporated herein by reference.

### TECHNICAL FIELD

The present application relates to the technical field of semiconductors, and in particular, to a semiconductor device layout structure and a method of forming a semiconductor device.

### BACKGROUND

With the development of large-scale semiconductor technologies, devices are becoming smaller and more integrated. In order to reduce costs, an area of a dicing lane is required to be reduced as much as possible on a single wafer, thus increasing a quantity of chips. However, process development requires arrangement of devices of more sizes. FIG. 1 is a schematic structural layout diagram of a conventional metal oxide semiconductor (MOS) device. Each device requires four probe contact test terminals (PAD) to be led out individually (a source, a drain, a gate, and a well area). This greatly limits a quantity of devices that can be put into a fixed dicing area.

### SUMMARY

According to a first aspect, the present application provides a semiconductor device layout structure, including:

an active area layout layer and a plurality of subdevice layout layers located on the active area layout layer, wherein each of the subdevice layout layers includes a gate pattern region, a source pattern region, and a drain pattern region; and the gate pattern regions of at least two of the subdevice layout layers are connected together and form a gate connection pattern region, the source pattern regions of the at least two of the subdevice layout layers are connected together and form a source connection pattern region, the gate connection pattern region is connected to a gate test terminal, and the source connection pattern region is connected to a source test terminal.

According to a second aspect, the present application further provides a method of forming a semiconductor device, including:

forming a well area layout layer on a substrate;

forming an active area layout layer on the well area layout layer, wherein the active area layout layer includes a first active area pattern region and a plurality of second active area pattern regions;

forming, on the active area layout layer, gate pattern regions, source pattern regions, and drain pattern regions that are in a one-to-one correspondence with the second active area pattern regions, wherein the active area layout layer and the gate pattern regions, the source pattern regions, and the drain pattern regions that are in a one-to-one correspondence with the second active area pattern regions form subdevice layout layers; and the gate pattern regions of at least two of the subdevice layout layers are connected together and form a gate connection pattern region, and the source pattern regions of the at least two of the subdevice layout layers are connected together and form a source connection pattern region;

forming a gate test terminal in the gate connection pattern region, wherein the gate test terminal is connected to the gate connection pattern region; and

forming a source test terminal in the source connection pattern region, wherein the source test terminal is connected to the source connection pattern region.

### BRIEF DESCRIPTION OF THE DRAWINGS

FIG. 1 is a schematic diagram of a conventional MOS device layout structure;

FIG. 2 is a schematic diagram of a semiconductor device layout structure according to an embodiment of the present application;

FIG. 3 is a schematic structural diagram of an active area layout layer in FIG. 2;

FIG. 4 is a schematic diagram of another semiconductor device layout structure according to an embodiment of the present application;

FIG. 5 is a schematic diagram of a method of forming a semiconductor device according to an embodiment of the present application;

FIG. 6A to FIG. 6F are each a preparation diagram of the structure in FIG. 4.

Reference numerals: 001—source; 002—drain; 003—gate; 004—well area; 100—active area layout layer; 110—first active area pattern region; 111—first stripe region; 112—second stripe region; 113—third stripe region; 120—second active area pattern region; 200—subdevice layout layer; 210—gate pattern region; 220—source pattern region; 221—second contact hole region; 230—drain pattern region; 231—third contact hole region; 240—gate auxiliary pattern region; 300—gate connection pattern region; 310—gate test terminal; 320—first gate connection pattern subregion; 321—first contact hole region; 400—source connection pattern region; 410—source test terminal; 500—drain test terminal; 600—drain conductive layer; 610—second contact structure; 700—well area layout layer; 800—well area connection pattern region; 810—fourth contact hole region; 900—well area test terminal.

### DETAILED DESCRIPTION

The technical solutions in embodiments of the present application are described below clearly and completely with reference to the drawings in the embodiments of the present application. Apparently, the described embodiments are merely part rather than all of the embodiments of the present application. All other embodiments obtained by those of ordinary skill in the art based on the embodiments of the present application without creative efforts should fall within the protection scope of the present application.

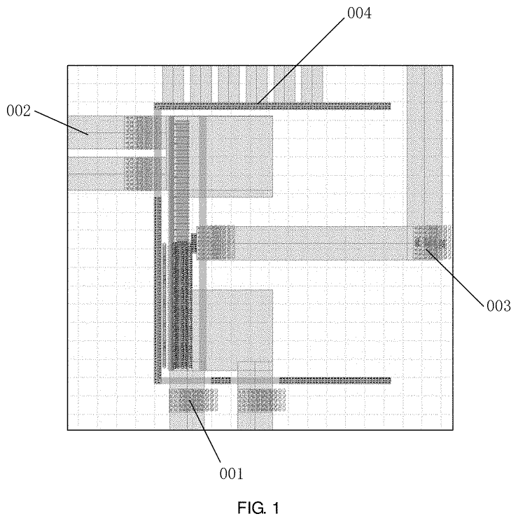

According to a first aspect, as shown in FIG. 1 to FIG. 4, an embodiment of the present application provides a semiconductor device layout structure, including: an active area layout layer 100 and a plurality of subdevice layout layers 200 located on the active area layout layer 100, wherein each subdevice layout layer 200 includes a gate pattern region 210, a source pattern region 220, and a drain pattern region 230; and gate pattern regions 210 of at least two subdevice layout layers 200 are connected together and form a gate connection pattern region 300, source pattern regions 220 of the at least two subdevice layout layers 200 are connected together and form a source connection pattern region 400, the gate connection pattern region 300 is connected to a gate test terminal 310, and the source connection pattern region 400 is connected to a source test terminal 410.

The semiconductor device layout structure is applicable to a layout structure design for a same type of devices. In this design, at least two devices share a source and a gate, that is, the gate pattern regions 210 of the at least two subdevice layout layers 200 are connected together and form the gate connection pattern region 300, and the gate connection pattern region 300 is connected to the gate test terminal 310, the source pattern regions 220 are connected together and form the source connection pattern region 400, and are connected to the source test terminal 410 through the source connection pattern region 400, to integrate MOS devices of different sizes into one test unit, and drain test terminals 500 are led out individually. For example, five MOS devices are to be integrated. In the conventional design, 20 PADs are required, while only eight PADs (including the gate test terminal 310, the source test terminal 410, a drain test terminal 500, and a well area test terminal 900) are required in the foregoing layout structure, such that a space occupied by the test unit can be greatly reduced, and the structure can also be configured for process structure representation.

Optionally, the gate pattern regions 210 of the plurality of subdevice layout layers 200 are connected together and form the gate connection pattern region 300, and the source pattern regions 220 of the plurality of subdevice layout layers 200 are connected together and form the source connection pattern region 400.

In a possible implementation, gate pattern regions 210 of all subdevice layout layers 200 in the semiconductor device layout structure are connected together and form the gate connection pattern region 300, and source pattern regions 220 of all the subdevice layout layers 200 in the semiconductor device layout structure are connected together and form the source connection pattern region 400, that is, all the subdevice layout layers 200 share a same gate connection pattern region 300 and are connected to a gate connection terminal through the gate connection pattern region 300, and all the subdevice layout layers 200 share a same source connection pattern region 400 and are connected to a source connection terminal through the source connection pattern region 400. Therefore, the semiconductor device layout structure requires only one gate connection terminal and one source connection terminal, thereby reducing an area occupied by the entire test unit due to a reduced quantity of gate connection terminals and a reduced quantity of source connection terminals.

Optionally, the plurality of gate pattern regions 210 are arranged along a first direction, and the gate connection pattern region 300 extends along the first direction. In a same subdevice layout layer 200, the drain pattern region 230 and the source pattern region 220 are respectively located on two sides of the gate pattern region 210 along the first direction.

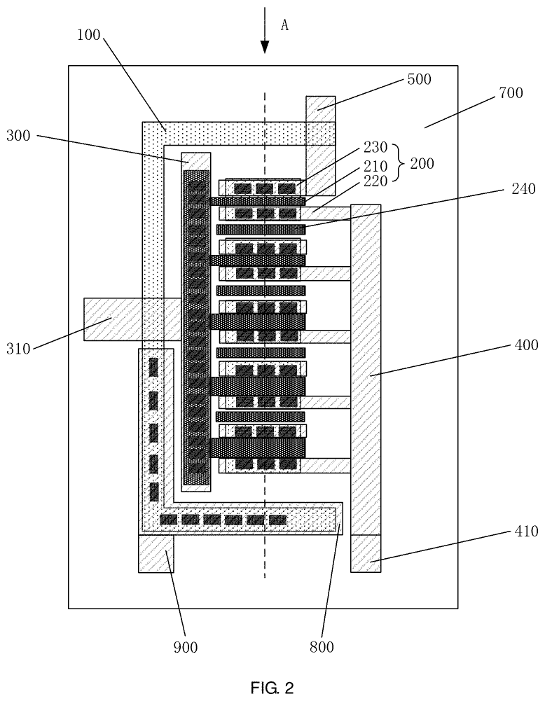

In a possible implementation, referring to FIG. 2, the semiconductor device layout structure includes five subdevice layout layers 200, such as five MOS devices of different sizes, and the five subdevice layout layers 200 share a same gate connection pattern region 300 and a same source connection pattern region 400. Five gate pattern regions 210 are spaced apart from each other along the first direction (that is, a direction A in FIG. 2), and a gate connection pattern region 300 shared by the five gate pattern regions 210 extends along the first direction. The drain pattern region 230 and the source pattern region 220 are respectively located on two sides of the gate pattern region 210 along the first direction. Such a structure is configured for transmission electron microscope (TEM) slicing along the first direction (a dotted line in FIG. 2), and actual sizes of five different devices can be verified in a single slicing operation. This greatly reduces a slicing time and cost, thereby effectively improving development efficiency of a process.

Optionally, a gate auxiliary pattern region 240 is provided between two adjacent gate pattern regions 210.

Optionally, in any two adjacent subdevice layout layers 200, along the first direction, the gate auxiliary pattern region 240 is located between the drain pattern region 230 of a previous subdevice layout layer 200 and the source pattern region 220 of a next subdevice layout layer 200.

It should be noted that, the gate auxiliary pattern region 240 is provided between the two adjacent subdevice layout layers 200, for example, a gate auxiliary pattern region, together with a source pattern region of one MOS device in adjacent MOS devices and a drain pattern region of the other MOS device in the adjacent MOS devices, can form an auxiliary MOS device, which is equivalent to a MOS field-effect transistor, thereby improving a body effect of the MOS device.

Optionally, the source connection pattern region 400 extends along the first direction.

It can be understood that, the source pattern regions 220 of the plurality of subdevice layout layers 200 are arranged along the first direction, and the source connection pattern region 400 extends along the first direction, facilitating wiring between the source connection pattern region 400 and each source pattern region 220, such that each source pattern region 220 only needs to be extended for connection to the source connection pattern region 400.

Optionally, the gate connection pattern region 300 and the source connection pattern region 400 are respectively located on two sides of each gate pattern region 210.

In a possible implementation, referring to FIG. 2, both the gate connection pattern region 300 and the source connection pattern region 400 shared by a plurality of subdevice layout layers 200 extend along the first direction, and each subdevice layout layer 200 is located between the gate connection pattern region 300 and the source connection pattern region 400, thereby avoiding interference between a line between the gate pattern region 210 and the gate connection pattern region 300 and a line between the source pattern region 220 and the source connection pattern region 400, and further reducing an area occupied by the entire semiconductor device layout structure.

Optionally, the semiconductor device layout structure further includes a well area layout layer 700, the active area layout layer 100 is located within a region of the well area layout layer 700, a well area connection pattern region 800 is formed on the well area layout layer 700, and the well area connection pattern region 800 is connected to a well area test terminal 900.

In a possible implementation, referring to FIG. 2, the subdevice layout layers 200 share one gate test terminal 310, one source test terminal 410, and one well area test terminal 900.

Optionally, the active area layout layer 100 includes a first active area pattern region 110 and a plurality of second active area pattern regions 120. The second active area pattern regions 120 are in a one-to-one correspondence with the gate pattern regions 210. The well area connection pattern region 800 is located within a region of the first active area pattern region 110.

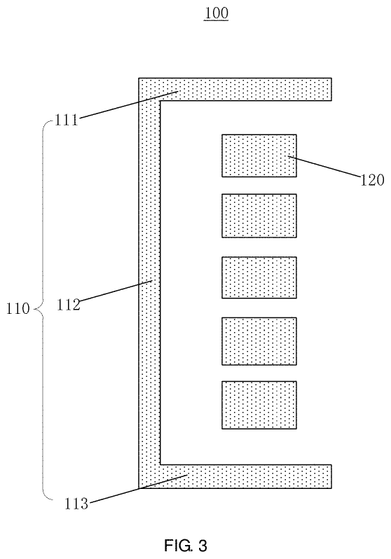

In a possible implementation, referring to FIG. 3 and with reference to FIG. 2, the active area layout layer 100 includes a first active area pattern region 110 and a plurality of second active area pattern regions 120. The first active area pattern region 110 half encloses the plurality of second active area pattern regions 120. Each second active area pattern region 120 corresponds to one subdevice layout layer 200. The well area connection pattern region 800 is located within a region of the first active area pattern region 110. The well area connection pattern region 800 is connected to a well area shared by all subdevices through a contact hole structure.

Optionally, the first active area pattern region 110 includes a first stripe region 111, a second stripe region 112, and a third stripe region 113 connected in sequence. The second stripe region 112 extends along the first direction. The first stripe region 111 and third stripe region 113 extend along a direction perpendicular to the first direction.

Referring to FIG. 3, in the first active area pattern region 110, the first stripe region 111 and the third stripe region 113 are provided in parallel and are both parallel to the gate pattern region 210, and the second stripe region 112 is parallel to the gate connection pattern region 300, allowing full utilization of a wafer area.

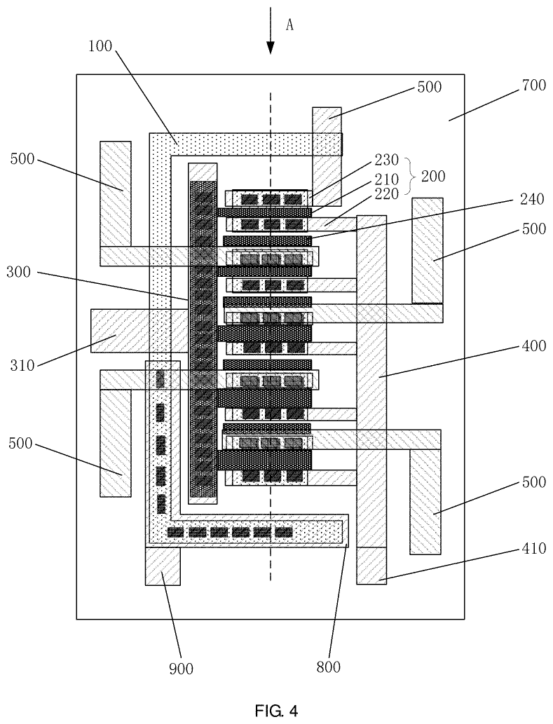

It should be noted that, for a same type of devices, those skilled in the art are more concerned about performance of MOS device drains. In this embodiment of the present application, the source test terminal 410, the gate test terminal 310, and the well area test terminal 900 are shared, a semiconductor device layout structure is provided, and referring to FIG. 4, MOS devices of different sizes are integrated into one test unit, and drain test terminals 500 are led out individually, such that an area occupied by the test unit can be greatly reduced, and the layout structure can also be configured for process structure representation.

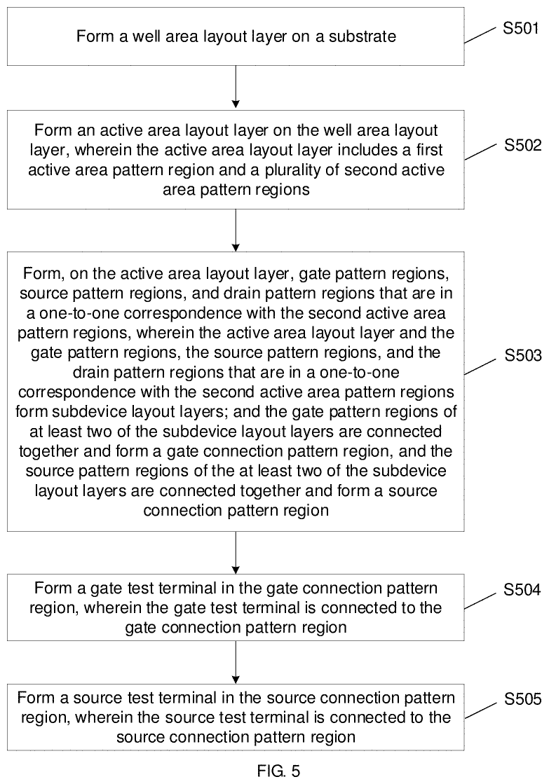

According to a second aspect, referring to FIG. 5, based on a same inventive concept, an embodiment of the present application further provides a method of forming a semiconductor device, including:

S501. Form a well area layout layer on a substrate.

S502. Form an active area layout layer on the well area layout layer, wherein the active area layout layer includes a first active area pattern region and a plurality of second active area pattern regions.

S503. Form, on the active area layout layer, gate pattern regions, source pattern regions, and drain pattern regions that are in a one-to-one correspondence with the second active area pattern regions, wherein the active area layout layer and the gate pattern regions, the source pattern regions, and the drain pattern regions that are in a one-to-one correspondence with the second active area pattern regions form subdevice layout layers; and gate pattern regions of at least two subdevice layout layers are connected together and form a gate connection pattern region, and source pattern regions of the at least two subdevice layout layers are connected together and form a source connection pattern region.

S504. Form a gate test terminal in the gate connection pattern region, wherein the gate test terminal is connected to the gate connection pattern region.

S505. Form a source test terminal in the source connection pattern region, wherein the source test terminal is connected to the source connection pattern region.

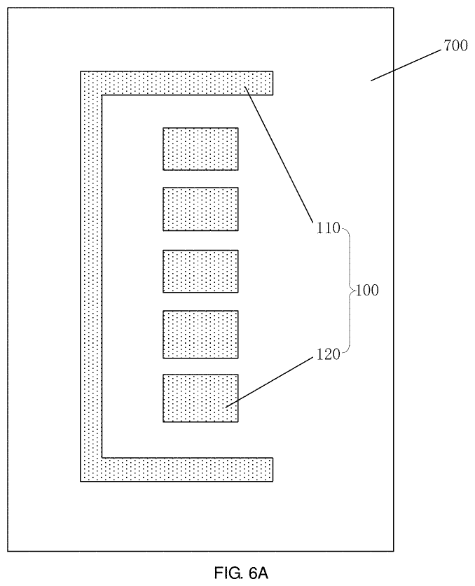

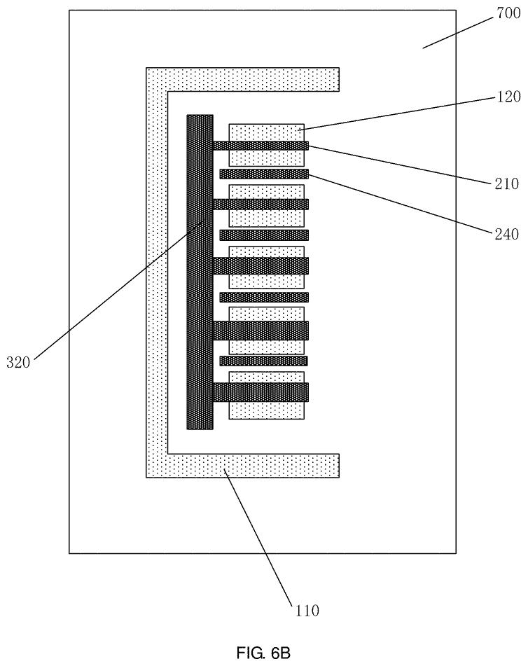

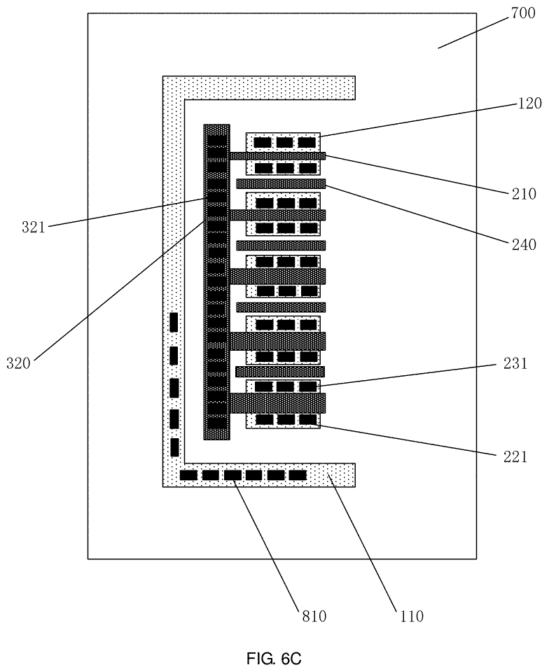

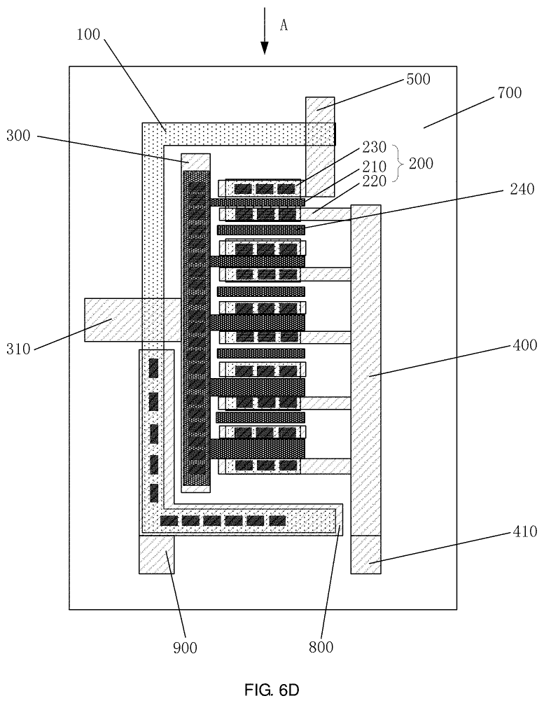

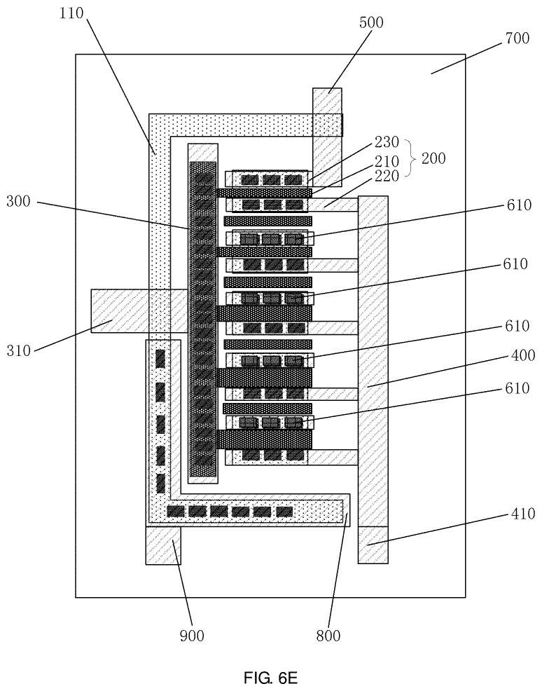

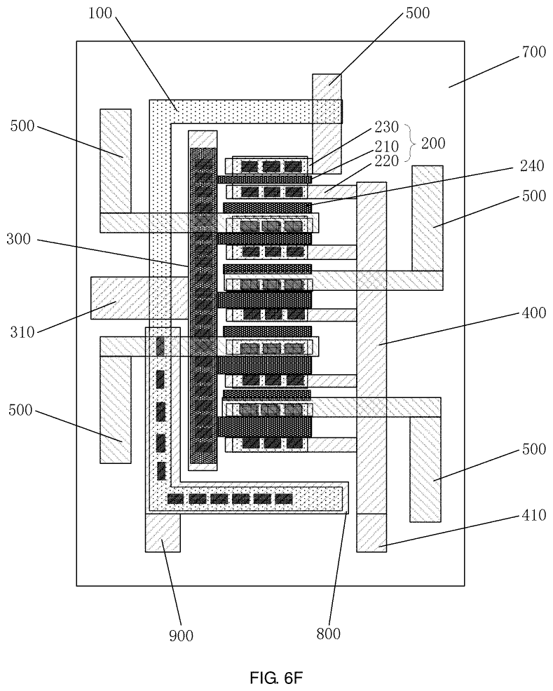

In a possible implementation, referring to FIG. 6A, an active area layout layer 100 is formed on a well area layout layer 700, and the active area layout layer 100 includes a first active area pattern region 110 and a plurality of second active area pattern regions 120.

Optionally, gate pattern regions of a plurality of subdevice layout layers are connected together and form the gate connection pattern region, and source pattern regions of the plurality of subdevice layout layers are connected together and form the source connection pattern region.

Optionally, the forming, on the active area layout layer, gate pattern regions, source pattern regions, and drain pattern regions that are in a one-to-one correspondence with the second active area pattern regions includes:

forming the gate pattern regions and a first gate connection pattern subregion on the active area layout layer through a patterning process, wherein at least two gate pattern regions are connected to the first gate connection pattern subregion;

forming a first interlayer dielectric layer on the gate pattern regions and the first gate connection pattern subregion;

forming a first contact structure in the first interlayer dielectric layer, wherein the first contact structure includes a first contact hole region, second contact hole regions, and third contact hole regions, the first contact hole region corresponds to the first gate connection pattern subregion, both the second contact hole regions and the third contact hole regions are in a one-to-one correspondence with the second active area pattern regions, and the second contact hole region and the third contact hole region are respectively located on two sides of the gate pattern region;

forming a first conductive layer on the first interlayer dielectric layer and the first contact structure, wherein the first conductive layer includes a second gate connection pattern subregion, a source connection pattern region, the source pattern regions, and drain conductive layers, wherein the second gate connection pattern subregion is connected to the first gate connection pattern subregion through the first contact hole region, and forms the gate connection pattern region, the source pattern regions are in a one-to-one correspondence with the second active area pattern regions, the source pattern region is connected to the second active area pattern region through the second contact hole region, the drain conductive layers are in a one-to-one correspondence with the second active area pattern regions, and the drain conductive layer is connected to the second active area pattern region through the third contact hole region;

forming a second interlayer dielectric layer on the first conductive layer, wherein the second interlayer dielectric layer covers the drain conductive layers;

forming second contact structures in the second interlayer dielectric layer; and

forming, on the second interlayer dielectric layer and the second contact structures, second conductive layers that are in a one-to-one correspondence with a plurality of drain conductive layers, the second conductive layer includes a drain pattern region and a drain test terminal, the drain pattern region is connected to the drain conductive layer through the second contact structure, and the drain test terminal is connected to the drain pattern region.

Optionally, a gate auxiliary pattern region is provided between any two adjacent second active area pattern regions.

In a possible implementation, referring to FIG. 6B, a gate pattern region 210 and a first gate connection pattern subregion 320 are formed on the active area layout layer 100 through a patterning process, gate pattern regions 210 are in a one-to-one correspondence with the second active area pattern regions 120, a plurality of gate pattern regions 210 are connected to the first gate connection pattern subregion 320, and a gate auxiliary pattern region 240 is provided between any two adjacent second active area pattern regions 120.

Optionally, the first contact structure further includes a fourth contact hole region, and the fourth contact hole region runs through the first active area pattern region.

The first conductive layer further includes a well area connection pattern region corresponding to the fourth contact hole region.

The method of forming a semiconductor device further includes:

forming a well area test terminal in the well area connection pattern region, wherein the well area test terminal is connected to the well area connection pattern region.

Optionally, the first conductive layer further includes the well area connection pattern region, and the well area connection pattern region is connected to the first active area pattern region through the fourth contact hole region.

In a possible implementation, referring to FIG. 6C, a first contact structure is formed on an upper layer of a region corresponding to the gate pattern region 210 and the first gate connection pattern subregion 320. The first contact structure includes a first contact hole region 321, a second contact hole region 221, a third contact hole region 231, and a fourth contact hole region 810. A region of the first contact hole region 321 corresponds to a region of the first gate connection pattern subregion 320. There are a plurality of second contact hole regions 221 and a plurality of third contact hole regions 231. Both the second contact hole regions 221 and the third contact hole regions 231 are in a one-to-one correspondence with the second active area pattern region 120, and in each group of corresponding second active area pattern region 120, second contact hole region 221, and third contact hole region 231, the second contact hole region 221 and the third contact hole region 231 are respectively located on two sides of the gate pattern region 210. A region of the fourth contact hole region 810 corresponds to a region of the first active area pattern region 110. Referring to FIG. 6D, through a patterning process, a second gate connection pattern subregion is formed on the first contact hole region 321, the second gate connection pattern subregion and the first gate connection pattern subregion 320 form the gate connection pattern region 300 through the first contact hole region 321, and a gate connection terminal is formed on a side of the gate connection pattern region 300 away from the gate pattern region 210. Source pattern regions 220 are respectively formed on all the second contact hole regions 221, a source connection pattern region 400 is formed at one end of a plurality of source pattern regions 220 away from the gate connection pattern region 300, the source connection pattern region 400 is connected to all the source pattern regions 220, and a source test terminal 410 is formed at one end of the source connection pattern region 400. Drain conductive layers 600 are respectively formed on all third contact hole regions 231. A well area connection pattern region 800 is formed on the fourth contact hole region 810, and a well area test terminal 900 extending along the first direction is formed at one end of the well area connection pattern region 800. It should be noted that, along the first direction, in the last subdevice layout layer 200, a drain conductive layer 600 may be used as a drain pattern region 230 in the subdevice layout layer 200, and a drain test terminal 500 of the subdevice layout layer 200 is formed at one end of the drain pattern region 230 away from the gate connection pattern region 300. For a method of forming a drain pattern region 230 for each of the other subdevice layout layers 200, refer to FIG. 6E and FIG. 6F. Referring to FIG. 6E, a second contact structure 610 is formed on a drain conductive layer 600 of each of the other subdevice layout layers 200. There are a plurality of second contact structures 610, and the second contact structures 610 are in a one-to-one correspondence with the drain conductive layers 600. Referring to FIG. 6F, through a patterning process, drain pattern regions 230 that are in a one-to-one correspondence with the second active area pattern region 120 are respectively formed on the second contact structures 610, a drain test terminal 500 is formed on one end of each drain pattern region 230, and drain test terminals 500 of two adjacent drain pattern regions 230 are respectively located on two sides of the second active area pattern region 120.

It should be noted that, referring to FIG. 6F, in this embodiment of the present application, five subdevices of a same type but different sizes are integrated into one test unit, source pattern regions, gate pattern regions, and well area layout layers of the five subdevices share a PAD, and the drain pattern regions are led out individually to be connected to the PAD. A conventional design requires 20 PADs, while this embodiment requires only eight PADs, which can greatly reduce a space occupied by a test unit. However, a quantity of subdevices is not limited to five, which may be increased or decreased according to actual requirements.

Those skilled in the art should understand that the embodiments of the present application may be provided as a method, a system, or a computer program product. Therefore, the present application may use a form of hardware only embodiments, software only embodiments, or embodiments with a combination of software and hardware. Moreover, the present invention may be in a form of a computer program product that is implemented on one or more computer-usable storage media (including but not limited to a magnetic disk memory, a CD-ROM, an optical memory, and the like) that include computer-usable program code.

The present application is described with reference to the flowcharts and/or block diagrams of the method, the device (system), and the computer program product according to the embodiments of the present application. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, such that the instructions executed by a computer or a processor of any other programmable data processing device generate an apparatus for implementing a specific function in one or more processes in the flowcharts and/or in one or more blocks in the block diagrams.

These computer program instructions may be stored in a computer readable memory that can instruct the computer or any other programmable data processing device to work in a specific manner, such that the instructions stored in the computer readable memory generate an artifact that includes an instruction apparatus. The instruction apparatus implements a specific function in one or more processes in the flowcharts and/or in one or more blocks in the block diagrams.

These computer program instructions may be loaded onto a computer or another programmable data processing device, such that a series of operations and steps are performed on the computer or the another programmable device, thereby generating computer-implemented processing. Therefore, the instructions executed on the computer or another programmable device provide steps for implementing a specific function in one or more processes in the flowcharts and/or in one or more blocks in the block diagrams.

Although some preferred embodiments of the present application have been described, those skilled in the art can make changes and modifications to these embodiments once they learn the basic inventive concept. Therefore, the appended claims are intended to be interpreted as including the preferred embodiments and all changes and modifications falling within the scope of the present application.

Obviously, those skilled in the art can make various modifications and variations to the embodiments of the present application without departing from the spirit and scope of the embodiments of the present application. The present application is intended to cover these modifications and variations provided that they fall within the scope of the claims of the present application and their equivalent technologies.

1. A semiconductor device layout structure, comprising:
an active area layout layer and a plurality of subdevice layout layers located on the active area layout layer, wherein each of the subdevice layout layers comprises a gate pattern region, a source pattern region, and a drain pattern region; and the gate pattern regions of at least two of the subdevice layout layers are connected together and form a gate connection pattern region, the source pattern regions of the at least two of the subdevice layout layers are connected together and form a source connection pattern region, the gate connection pattern region is connected to a gate test terminal, and the source connection pattern region is connected to a source test terminal.

2. The semiconductor device layout structure according to claim 1, wherein the gate pattern regions of the plurality of subdevice layout layers are connected together and form the gate connection pattern region, and the source pattern regions of the plurality of subdevice layout layers are connected together and form the source connection pattern region.

3. The semiconductor device layout structure according to claim 1, wherein a plurality of the gate pattern regions are arranged along a first direction, and the gate connection pattern region extends along the first direction; and
in a same subdevice layout layer, the drain pattern region and the source pattern region are respectively located on two sides of the gate pattern region along the first direction.

4. The semiconductor device layout structure according to claim 3, wherein a gate auxiliary pattern region is provided between two adjacent gate pattern regions.

5. The semiconductor device layout structure according to claim 4, wherein in any two adjacent subdevice layout layers, along the first direction, the gate auxiliary pattern region is located between the drain pattern region of a previous subdevice layout layer and the source pattern region of a next subdevice layout layer.

6. The semiconductor device layout structure according to claim 3, wherein the source connection pattern region extends along the first direction.

7. The semiconductor device layout structure according to claim 6, wherein the gate connection pattern region and the source connection pattern region are respectively located on two sides of each of the gate pattern regions.

8. The semiconductor device layout structure according to claim 3, the semiconductor device layout structure further comprising a well area layout layer, wherein the active area layout layer is located within a region of the well area layout layer, a well area connection pattern region is formed on the well area layout layer, and the well area connection pattern region is connected to a well area test terminal.

9. The semiconductor device layout structure according to claim 8, wherein the active area layout layer comprises a first active area pattern region and a plurality of second active area pattern regions, and the second active area pattern regions are in a one-to-one correspondence with the gate pattern regions; and
the well area connection pattern region is located within a region of the first active area pattern region.

10. The semiconductor device layout structure according to claim 9, wherein the first active area pattern region comprises a first stripe region, a second stripe region, and a third stripe region connected in sequence, the second stripe region extends along the first direction, and the first stripe region and the third stripe region extend along a direction perpendicular to the first direction.

11. A method of forming a semiconductor device, comprising:
forming a well area layout layer on a substrate;
forming an active area layout layer on the well area layout layer, wherein the active area layout layer comprises a first active area pattern region and a plurality of second active area pattern regions;
forming, on the active area layout layer, gate pattern regions, source pattern regions, and drain pattern regions that are in a one-to-one correspondence with the second active area pattern regions, wherein the active area layout layer and the gate pattern regions, the source pattern regions, and the drain pattern regions that are in a one-to-one correspondence with the second active area pattern regions form subdevice layout layers; and the gate pattern regions of at least two of the subdevice layout layers are connected together and form a gate connection pattern region, and the source pattern regions of the at least two of the subdevice layout layers are connected together and form a source connection pattern region;
forming a gate test terminal in the gate connection pattern region, wherein the gate test terminal is connected to the gate connection pattern region; and
forming a source test terminal in the source connection pattern region, wherein the source test terminal is connected to the source connection pattern region.

12. The method according to claim 11, wherein the gate pattern regions of a plurality of the subdevice layout layers are connected together and form a gate connection pattern region, and the source pattern regions of the plurality of the subdevice layout layers are connected together and form a source connection pattern region.

13. The method according to claim 12, wherein the forming, on the active area layout layer, gate pattern regions, source pattern regions, and drain pattern regions that are in a one-to-one correspondence with the second active area pattern regions comprises:
forming the gate pattern regions and a first gate connection pattern subregion on the active area layout layer through a patterning process, wherein at least two of the gate pattern regions are connected to the first gate connection pattern subregion;
forming a first interlayer dielectric layer on the gate pattern regions and the first gate connection pattern subregion;
forming a first contact structure in the first interlayer dielectric layer, wherein the first contact structure comprises a first contact hole region, second contact hole regions, and third contact hole regions, the first contact hole region corresponds to the first gate connection pattern subregion, both the second contact hole regions and the third contact hole regions are in a one-to-one correspondence with the second active area pattern regions, and the second contact hole region and the third contact hole region are respectively located on two sides of the gate pattern region;
forming a first conductive layer on the first interlayer dielectric layer and the first contact structure, wherein the first conductive layer comprises a second gate connection pattern subregion, the source connection pattern region, the source pattern regions, and drain conductive layers, wherein the second gate connection pattern subregion is connected to the first gate connection pattern subregion through the first contact hole region, and forms the gate connection pattern region, the source pattern regions are in a one-to-one correspondence with the second active area pattern regions, the source pattern region is connected to the second active area pattern region through the second contact hole region, the drain conductive layers are in a one-to-one correspondence with the second active area pattern regions, and the drain conductive layer is connected to the second active area pattern region through the third contact hole region;
forming a second interlayer dielectric layer on the first conductive layer, wherein the second interlayer dielectric layer covers the drain conductive layers;
forming second contact structures in the second interlayer dielectric layer; and
forming, on the second interlayer dielectric layer and the second contact structures, second conductive layers that are in a one-to-one correspondence with a plurality of the drain conductive layers, the second conductive layer comprises the drain pattern region and a drain test terminal, the drain pattern region is connected to the drain conductive layer through the second contact structure, and the drain test terminal is connected to the drain pattern region.

14. The method according to claim 13, wherein a gate auxiliary pattern region is provided between any two adjacent second active area pattern regions.

15. The method according to claim 13, wherein the first contact structure further comprises a fourth contact hole region, and the fourth contact hole region runs through the first active area pattern region;
the first conductive layer further comprises a well area connection pattern region corresponding to the fourth contact hole region; and
the method of forming a semiconductor device further comprises:
forming a well area test terminal in the well area connection pattern region, wherein the well area test terminal is connected to the well area connection pattern region.

16. The method according to claim 15, wherein the first conductive layer further comprises the well area connection pattern region, and the well area connection pattern region is connected to the first active area pattern region through the fourth contact hole region.
